(19) United States
(12) Patent Application Publication
(10) Pub. No.: US 2017/0244019 A1
(43) Pub. Date: Aug. 24, 2017

(54) FLEXIBLE AND FOLDABLE PAPER-SUBSTRATE THERMOELECTRIC GENERATOR (TEG)

(71) Applicant: KING ABDULLAH UNIVERSITY OF SCIENCE AND TECHNOLOGY, Thuwal (SA)

(72) Inventors: Jhonathan Prieto ROJAS, Thuwal (SA); Muhammad Mustafa HUSSAIN, Austin, TX (US)

(21) Appl. No.: 15/434,763

(22) Filed: Feb. 16, 2017

Related U.S. Application Data
(60) Provisional application No. 62/297,389, filed on Feb. 19, 2016.

(51) Int. Cl. H01L 35/32; H01L 35/34; H01L 35/16

(52) U.S. Cl. CPC H01L 35/32; H01L 35/16; H01L 35/34

(57) ABSTRACT

Flexible and foldable paper-substrate thermoelectric generators (TEGs) and methods for making the paper-substrate TEGs are disclosed. A method includes depositing a plurality of thermocouples in series on a paper substrate to create a paper-substrate TEG, wherein the plurality of thermocouples is deposited between two contact points of the paper-substrate TEG. The method may also include setting the power density and maximum achievable temperature gradient of the paper-substrate TEG by folding the paper-substrate TEG. A paper-substrate TEG apparatus may include a paper substrate and a plurality of thermocouples deposited in series on the paper substrate between two contact points of the paper-substrate TEG, wherein the power density and maximum achievable temperature gradient of the paper-substrate TEG is set by folding the paper-substrate TEG.

### CROSS-REFERENCE TO RELATED PATENT APPLICATIONS

This application claims priority and benefit from U.S. Provisional Patent Application No. 62/297,389, filed Feb. 19, 2016, for “FLEXIBLE AND FOLDABLE PAPER-SUBSTRATE THERMOELECTRIC GENERATOR (TEG),” the entire contents of which are incorporated in their entirety herein by reference.

### FIELD OF THE DISCLOSURE

The instant disclosure relates to thermoelectric generators (TEGs). More specifically, this disclosure relates to a flexible and foldable paper-substrate TEG and a method for making a flexible and foldable paper-substrate TEG.

### BACKGROUND

One of the few common characteristics of all electronics is that they all generate heat as a result of the workings of the underlying circuitry. Because electronics are a staple component in our everyday lives and the number of new electronics available in the market increases each year, a significant amount of heat is generated each year from electronics alone. Heat is also generated from numerous sources other than electronics, including the human body. This generated heat, also referred to as “waste heat,” is a ubiquitous and very accessible energy resource. Thus, waste heat is recognized as a potential environmentally friendly energy source capable of supporting increasing energy demand.

Thermoelectric generators (TEGs) are one conventional device used to harvest this waste heat. Current efforts in the development of TEGs have been directed towards the creation of novel materials or composites of diverse materials for use as the material in the TEG providing the thermoelectric effect. Numerous drawbacks, however, are associated with currently-available TEGs. In particular, conventional TEGs are not affordable, and thus not commercially viable. Another drawback is the lack of accessibility to the materials and precursor materials used as the thermoelectric material of a TEG. Moreover, the conventional thermoelectric materials employed in TEGs tend to have little or no flexibility.

### SUMMARY

The affordability, accessibility, and flexibility of a thermoelectric generator (TEG) may be improved by employing paper as the hosting substrate for the thermoelectric materials that provide the thermoelectric effect for the TEG. The paper-based TEGs may be used, for example, in wearable clothing to harvest energy from body heat and channeled, e.g., to recharge portable devices. Another non-limiting exemplary use for paper-based TEGs may be with electronic devices to harvest energy from an electronic device and channel the energy, e.g., to recharge or power the same or a different electronic device. The paper substrate may be folded to improve power density of the paper-based TEGs.

In one embodiment, a method for making a paper-substrate TEG may include depositing a plurality of thermocouples in series on a paper substrate to create a paper-substrate TEG, wherein the plurality of thermocouples is deposited between two contact points of the paper-substrate TEG. The method may also include setting the power density and maximum achievable temperature gradient of the paper-substrate TEG by folding the paper-substrate TEG. According to another embodiment, a paper-substrate TEG apparatus may include a paper substrate and a plurality of thermocouples deposited in series on the paper substrate between two contact points of the paper-substrate TEG, wherein the power density and maximum achievable temperature gradient of the paper-substrate TEG is set by folding the paper-substrate TEG.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the concepts and specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features that are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the disclosed systems and methods, reference is now made to the following descriptions taken in conjunction with the accompanying drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 provides a flow chart illustrating a method for making a paper-substrate TEG according to one embodiment of the disclosure.

FIG. 2A is a schematic diagram illustrating a paper-based TEG with thermocouples deposited on a paper substrate according to one embodiment of the disclosure.

FIG. 2B is a schematic diagram illustrating the flexibility of a paper-substrate TEG according to one embodiment of the disclosure.

FIG. 2C is a schematic diagram illustrating the adjusting of the power density of a paper-substrate TEG according to one embodiment of the disclosure.

FIG. 3 is a schematic diagram illustrating a paper-substrate TEG according to one embodiment of the disclosure.

### DETAILED DESCRIPTION

Paper is a cheap ubiquitous material, making it highly affordable and accessible. Most paper also has low thermal and electrical conductivity, making it an appropriate substrate for a thermoelectric generator (TEG). Mechanically, paper tends to be flexible, with the ability to bend and stretch to conform to the shape of an object, such as an electronic device, on which it is attached. Thus, given the affordability, accessibility, and flexibility of paper, paper-based substrates, whether standard paper or a composite of paper-based materials, such as polyester paper, may improve the characteristics of a TEG developed on the paper-based substrate.

In addition to generating electricity and harvesting energy, a paper-based TEG has numerous applications. For example, because of the improved flexibility of a TEG that employs a paper substrate, a flexible TEG may be used with flexible electronics, such as human-wearable electronics. TEGs in wearable electronics have the unique advantage of being able to use human body heat to generate electricity and power sensors, devices, displays, and other electronic components integrated into the wearable electronic system. Another key advantage to using TEGs in electronics, including wearable electronics, is the ability to reuse heat from the electronic device or the human body to transform thermal energy into electric energy to charge a battery and extend the battery life of the device.

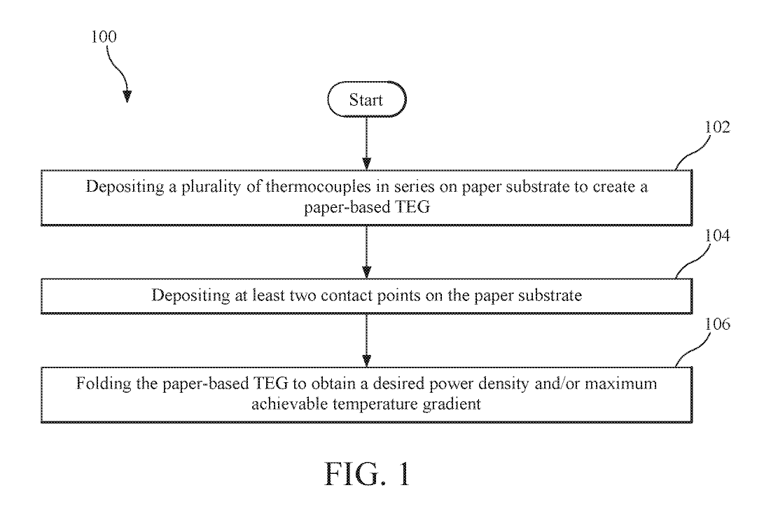

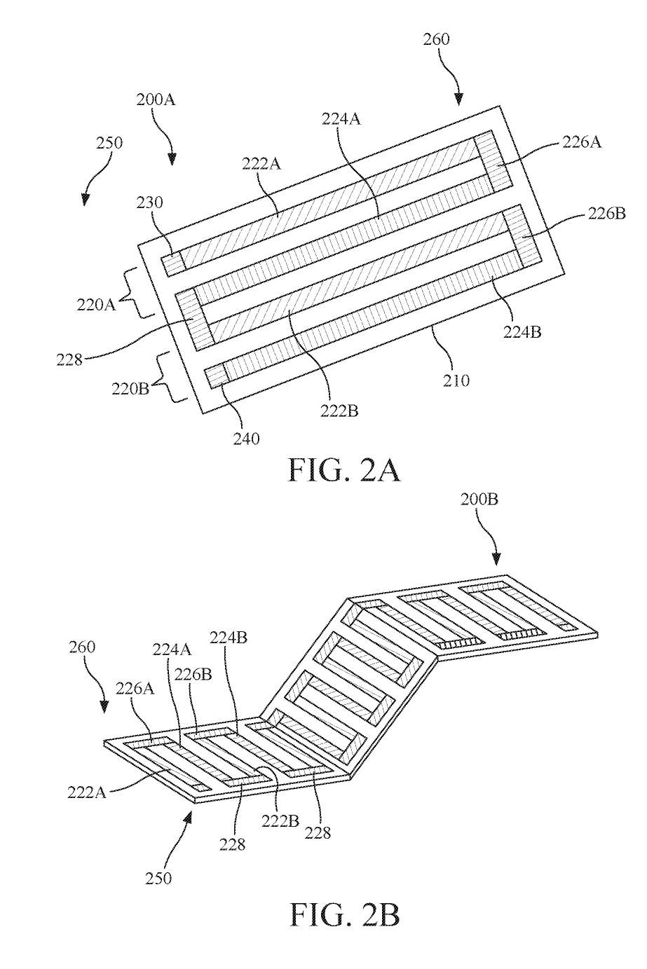

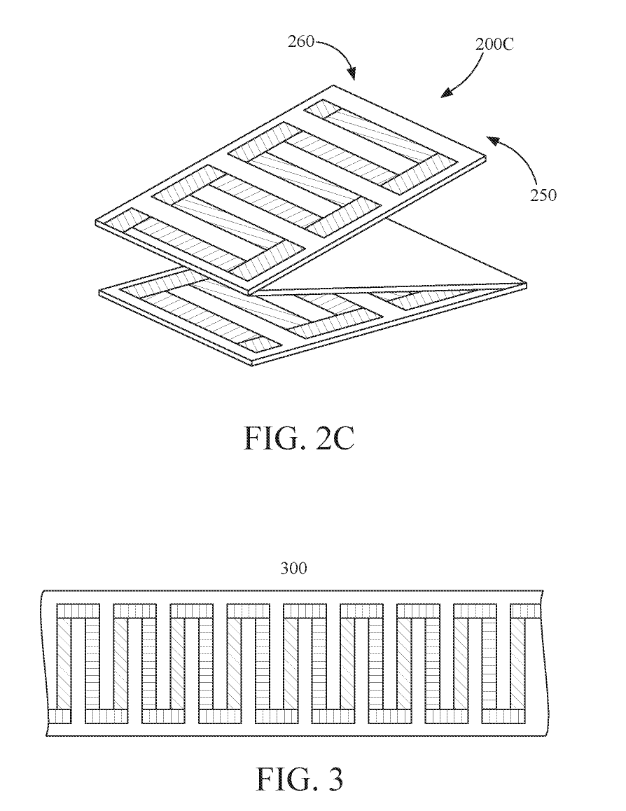

FIG. 1 provides a flow chart illustrating a method for making a paper-substrate TEG according to one embodiment of the disclosure. The method 100, and variations thereof, may be implemented to produce the systems and embodiments described with respect to FIGS. 2-3. In general, embodiments of method 100 may be implemented by other similar systems without deviating from this disclosure.

Method 100 begins, at block 102, with depositing a plurality of thermocouples in series on a paper substrate to create a paper-based TEG. At block 104, the method 100 may also include depositing at least two contact points. The plurality of thermocouples may be coupled between the at least two contact points of the paper-substrate TEG. Blocks 102 and 104 may be reversed such that the at least two contact points are deposited before the plurality of thermocouples. Then, at block 106, the paper-based TEG may be folded to obtain a desired power density and/or maximum achievable temperature gradient. One example of a TEG manufactured by the method 100 is shown in FIG. 2A. FIG. 2A is a schematic diagram illustrating a paper-based TEG with thermocouples deposited on a paper substrate according to one embodiment of the disclosure.

Generally, the paper substrate 210 may be any paper-based material. A paper-based material may be any thin and flexible fibrous material usually intended for uses such as printing, writing, cleaning and packaging, among others. The choice of a particular paper-based material to use as the paper substrate 210 may be driven by the application for the TEG. For example, paper-based materials which may be used as paper substrate 210 may include standard paper or polyester paper. Standard paper may be a flexible thin material produced by pressing and drying wet fibers of cellulose pulp, which may come from grass, wood, rags, or the like. Polyester paper may be a urethane-coated woven polyester fabric used with applications such as tearless printing paper. In some embodiments, the polyester paper may be tearless, stiff, waterproof, extra-smooth paper, and heat-stable paper-based material.

In some embodiments, each thermocouple 220A-B of the plurality of thermocouples 220 deposited on paper substrate 210 may include a pair of inorganic thermoelectric materials. Each thermoelectric material of the thermocouples 220 may have a width of approximately two millimeters, a length of approximately three and a half centimeters, and a thickness of approximately seven hundred and fifty nanometers. Alternatively, each thermoelectric material of the thermocouples 220 may have a width of approximately one millimeter, a length of approximately eight millimeters, and a thickness of approximately two micrometers. However, the width, length, and thickness may vary depending on the application and available toolsets.

For example, the pair of inorganic thermoelectric materials in each thermocouple 220 of TEG 200 illustrated in FIGS. 2A-C may be bismuth telluride (Bi₂Te₃) 222 and antimony telluride (Sb₂Te₃) 224. However, as with the choice of the paper-based substrate 210, the choice of the particular inorganic materials to use as the pair of thermoelectric materials to deposit on the paper-based substrate to provide the thermoelectric effect for the TEG may be driven by the application for the TEG. For example, the choice may be driven by the figure of merit (ZT) desired for the thermoelectric materials. A common ZT is defined as:

$$ZT = \frac{PF \cdot T}{κ} = \frac{{S}^{2} \cdot σ \cdot T}{κ} , \qquad ( 1 )$$

where (PF=S²σ) is the power factor, S is the Seebeck coefficient, σ is the electric conductance, κ is the thermal conductance, and T is the temperature. A thermoelectric material will yield a good ZT by having low thermal conductivity so as to maintain a larger temperature difference, a high Seebeck coefficient so as to achieve higher Seebeck voltages, and a high electrical conductivity so as to have a larger short-circuit current. Materials that tend to have good ZTs, making them good thermoelectric materials, include bismuth telluride (Bi₂Te₃) and antimony telluride (Sb₂Te₃). However, other materials may be used without departing from this disclosure in spirit or scope.

Referring back to FIG. 1, block 102 of depositing the plurality of thermocouples 220 may include depositing the inorganic thermoelectric materials of a thermocouple 220 by physical vapor deposition (PVD) magnetron sputtering. For example, each of the thermoelectric materials, such as bismuth telluride (Bi₂Te₃) and antimony telluride (Sb₂Te₃), may be sequentially deposited via PVD magnetron sputtering.

Masks may be used to aid the deposition process. For example, standard hard masks, such as a Kapton hard mask or a shadow mask may be used. For example, a shadow mask may be defined on a vinyl paper adhesive material using a micromachining CO₂ engraving laser. Because the shadow mask may be in direct and fixed contact with the substrate, its use may allow for higher resolution features to be more accurately defined during the deposition process.

As illustrated in FIG. 2B, for each thermocouple of the plurality of thermocouples 220, contact pads may be deposited at an end of each thermocouple and on top of the inorganic materials of the thermocouple to create contact between the inorganic materials. For example, in FIG. 2B, contact 226A creates contact between thermoelectric materials 222A and 224A and contact 226B creates contact between thermoelectric materials 222B and 224B. In some embodiments, contacts 226 may include material from one or both of the thermoelectric materials 222 and 224. In other embodiments, contacts 226 may be a different material that also has good electrical conductivity. For example, contact 226 may include gold (Au), aluminum (Al), copper (Cu), and/or alloys of those materials.

Contact pads may also be deposited between each thermocouple to create contact between the series-connected thermocouples. In some embodiments, contacts 228 between thermocouple pairs may be made of the same material as contacts 226. In another embodiment, contacts 228 may be made of different materials as contact 226.

The voltage output of TEG 200A, 200B, 200C illustrated in FIGS. 2A, 2B, and 2C may be approximated as the sum of the junction voltage differentials. In particular, the voltage across thermoelectric material 222A may be the voltage between contact 230 and contact 226A. The voltage generated by the thermoelectric materials 222 and 224 may be a function of the temperature difference between the contacts on each side of paper-substrate 210. For example, one side, such as side 250, may be at a first temperate and another side, such as side 260, may be at a different temperature. Based on the difference in temperature between the two sides, side 250 and side 260, thermoelectric material 222 may generate a voltage. Thermoelectric material 224 may also generate a voltage based on the difference in temperature between the two sides 250 and 260 of paper-substrate 210. Because each thermoelectric material 222 and 224 in a thermocouple 220 is series connected and because each thermocouple 220 is series-connected, the overall voltage across the terminals, such as contact 230 and contact 240, of the TEG may be approximated as the sum of the voltages of each thermoelectric material, or equivalently the sum of the voltages of each thermocouple.

Returning to FIG. 1, at block 104, method 100 includes setting the power density and maximum achievable temperature gradient of the paper-substrate TEG by folding the paper-substrate TEG. As an example, FIGS. 2B and 2C provide schematic diagrams illustrating the folding of TEG 200, which may be used to set or adjust the power density and/or maximum achievable temperature gradient of TEG 200A, 200B, 200C according to embodiments of the disclosure. The generated voltage may be a function of the temperature difference between side 250 and side 260 of TEG 200A, 200B, 200C. By folding TEG 200A, 200B, 200C, side 260 may be further isolated from side 250 in the depth direction, thereby increasing the maximum achievable temperature gradient. In addition, by folding TEG 200B, 200C as illustrated in FIGS. 2B and 2C, the surface area of TEG 200 may be reduced, thereby increasing the power density of paper-substrate TEG 200B, 200C. In some embodiments, TEG may be folded differently than originally folded to adjust the power density and/or maximum achievable temperature gradient. For example, TEG 200A, 200B, 200C may be stretched to further isolate side 250 from side 260. In general, however, folding may include folding in any direction.

In general, TEG 200A, 200B, 200C may be folded in a variety of different ways without departing from this disclosure in spirit or scope. For example, paper-folding techniques, such as origami, accordion, kirigami, or fan type folding may be utilized to set or adjust the power density and/or maximum achievable temperature gradient of TEG 200A, 200B, 200C.

The number of thermocouples included in a TEG developed in accordance with embodiments of this disclosure is not limited to the number of thermocouples illustrated in, e.g., FIG. 2A. For example, as illustrated in FIG. 3, the number of thermocouples in a TEG developed in accordance with this disclosure may be more than two thermocouples illustrated in FIG. 2A.

As illustrated in FIGS. 2A-C and 3, a paper-substrate TEG includes a paper substrate and a plurality of thermocouples deposited in series on the paper substrate between two contact points of the paper-substrate TEG, wherein the power density and maximum achievable temperature gradient of the paper-substrate TEG are set by folding the paper-substrate TEG. According to one embodiment, the paper substrate may include standard paper or polyester paper. As illustrated in FIGS. 2A-C and 3, in some embodiments, the plurality of thermocouples may include a pair of inorganic materials. According to an embodiment, the pair of inorganic materials may include bismuth telluride (Bi₂Te₃) and antimony telluride (Sb₂Te₃). The inorganic materials serving as the thermoelectric materials may be deposited by physical vapor deposition (PVD) magnetron sputtering. In an embodiment, for each thermocouple of the plurality of thermocouples, contact pads located at an end of a thermocouple and on top of the inorganic materials of the thermocouple create contact between the inorganic materials. According to an embodiment, a TEG of this disclosure may be constructed in accordance with method 100 using basic micromachining and microfabrication techniques, making the TEG of this disclosure more accessible and cheap.

In some embodiments, the power density and maximum achievable temperature gradient of the paper-substrate TEG is capable of being adjusted by folding the paper-substrate TEG differently than originally folded. The folding used to set the power density and maximum achievable temperature gradient of the paper-substrate TEG comprises at least one of origami, accordion, and fan type folding.

The schematic flow chart diagram of FIG. 1 is generally set forth as a logical flow chart diagram. As such, the depicted order and labeled steps are indicative of one embodiment of the disclosed method. While, for purposes of simplicity of explanation, methodologies are shown and described as a series of acts/blocks, it is to be understood and appreciated that the claimed subject matter is not limited by the number or order of blocks, as some blocks may occur in different orders and/or at substantially the same time with other blocks from what is depicted and described herein. Moreover, not all illustrated blocks may be required to implement methodologies described herein. It is to be appreciated that functionality associated with blocks may be implemented by various aspects of the systems disclosed herein. Other steps and methods may be conceived that are equivalent in function, logic, or effect to one or more steps, or portions thereof, of the illustrated methods. Additionally, the format and symbols employed are provided to explain the logical steps of the methods and are understood not to limit the scope of the methods. Although various arrow types and line types may be employed in the flow chart diagrams, they are understood not to limit the scope of the corresponding methods. Indeed, some arrows or other connectors may be used to indicate only the logical flow of the methods. For instance, an arrow may indicate a waiting or monitoring period of unspecified duration between enumerated steps of the depicted methods. Additionally, the order in which a particular method occurs may or may not strictly adhere to the order of the corresponding steps shown.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the present invention, disclosure, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A paper-substrate thermoelectric generator (TEG) apparatus, comprising:
a paper substrate; and
a plurality of thermocouples in series on the paper substrate; and
at least two contact points on the paper substrate, wherein the plurality of thermocouples are coupled between the at least two contact points of the paper-substrate TEG.

2. The apparatus of claim 1, wherein the paper substrate comprises standard paper or polyester paper.

3. The apparatus of claim 1, wherein each of the plurality of thermocouples comprises a pair of inorganic materials.

4. The apparatus of claim 3, wherein the pair of inorganic materials comprises bismuth telluride (Bi₂Te₃) and antimony telluride (Sb₂Te₃).

5. The apparatus of claim 3, wherein the pair of inorganic materials are selected according to a figure of merit (ZT):
$$ZT = \frac{PF \cdot T}{κ} = \frac{{S}^{2} \cdot σ \cdot T}{κ}$$
where (PF=S²σ) is a power factor, S is a Seebeck coefficient, σ is an electric conductance, κ is a thermal conductance, and T is a temperature.

6. The apparatus of claim 3, wherein the inorganic materials of a thermocouple are deposited by physical vapor deposition (PVD) magnetron sputtering.

7. The apparatus of claim 1, further comprising, for each thermocouple of the plurality of thermocouples, contact pads located at an end of a thermocouple and on top of the inorganic materials of the thermocouple, wherein the contact pads create contact between the inorganic materials.

8. The apparatus of claim 7, wherein the contact pads are formed of same material as the at least two contact points.

9. The apparatus of claim 1, wherein the paper substrate is folded, and wherein the folding adjusts at least one of a power density and a maximum achievable temperature gradient of the paper-substrate TEG.

10. The apparatus of claim 1, wherein the paper substrate is folded according to at least one of origami, accordion, and fan type folding.

11. A method, comprising:
depositing a plurality of thermocouples in series on a paper substrate to create a paper-based TEG; and
depositing at least two contact points on the paper substrate, wherein the plurality of thermocouples contacts the at least two contact points.

12. The method of claim 11, wherein the paper substrate comprises standard paper or polyester paper.

13. The method of claim 11, wherein each of the plurality of thermocouples comprises a pair of inorganic materials.

14. The method of claim 13, wherein the pair of inorganic materials comprises bismuth telluride (Bi₂Te₃) and antimony telluride (Sb₂Te₃).

15. The method of claim 13, wherein the pair of inorganic materials are selected according to a figure of merit (ZT):
$$ZT = \frac{PF \cdot T}{κ} = \frac{{S}^{2} \cdot σ \cdot T}{κ}$$
where (PF=S²94 ) is a power factor, S is a Seebeck coefficient, σ is an electric conductance, κ is a thermal conductance, and T is a temperature.

16. The method of claim 13, wherein depositing comprises depositing the inorganic materials of a thermocouple by physical vapor deposition (PVD) magnetron sputtering.

17. The method of claim 11, further comprising, for each thermocouple of the plurality of thermocouples, depositing contact pads at an end of a thermocouple and on top of the inorganic materials of the thermocouple to create contact between the inorganic materials.

18. The method of claim 11, further comprising folding the paper-substrate after deposition of the plurality of thermocouples, wherein the folding adjusts at least one of a power density and a maximum achievable temperature gradient.

19. The method of claim 18, wherein the contact pads are formed of same material as the at least two contact points.

20. The method of claim 11, wherein the step of folding comprises at least one of origami, accordion, and fan type folding.
